(19) United States
(12) Patent Application Publication
(10) Pub. No.: US 2026/0101575 A1
(43) Pub. Date: Apr. 9, 2026

(54) SEMICONDUCTOR DEVICE

(71) Applicant: Samsung Electronics Co., Ltd., Suwon-si (KR)

(72) Inventors: Taeyong KWON, Suwon-si (KR); Seon-Bae KIM, Suwon-si (KR); Changhee KIM, Suwon-si (KR)

(73) Assignee: Samsung Electronics Co., Ltd., Suwon-si (KR)

(21) Appl. No.: 19/169,155

(22) Filed: Apr. 3, 2025

(30) Foreign Application Priority Data
Oct. 7, 2024 (KR) 10-2024-0135667

(51) Int. Cl. H10D 84/83; H10D 30/00; H10D 30/01; H10D 30/43; H10D 30/62; H10D 62/10; H10D 62/13; H10D 64/23; H10D 64/62; H10D 84/01

(52) U.S. Cl. CPC H10D 84/8312; H10D 30/43; H10D 30/502; H10D 30/6211; H10D 30/6219; H10D 62/121; H10D 62/151; H10D 64/251; H10D 64/62; H10D 84/83138; H10D 84/832; H10D 84/834; H10D 30/024; H10D 84/013; H10D 84/0158

(57) ABSTRACT

A semiconductor device includes a substrate, a first channel pattern on the substrate, the first channel pattern having a first width, a first gate electrode extending in a second direction, a first gate capping pattern on an upper surface of the first gate electrode, a second channel pattern spaced apart from the first channel pattern, the first channel pattern having a second width, a second gate electrode extending in the second direction on the second channel pattern, a second gate capping pattern on an upper surface of the second gate electrode, a source/drain pattern on at least one side of the second channel pattern, a first source/drain contact connected to the source/drain pattern, a second source/drain contact spaced apart from the first source/drain contact, and a contact isolation film between the first source/drain contact and the second source/drain contact. The second width is greater than the first width.

### CROSS REFERENCE TO RELATED APPLICATION

This application claims priority to Korean Patent Application No. 10-2024-0135667, filed in the Korean Intellectual Property Office on Oct. 7, 2024, the entire contents of which are hereby incorporated by reference.

### BACKGROUND

Some example embodiments relate to a semiconductor device.

A semiconductor device is a core component used to control and/or amplify an electrical signal in an electronic device, and various types of semiconductor devices may be manufactured. For example, a memory device may be mainly used to store and retrieve data, while a non-memory device may be used to control and/or amplify an electrical signal. The semiconductor device is a core component of an electronic device and plays an important role in various fields including computers, communication equipment, consumer electronics, etc.

With the continual advancement of the semiconductor industry, the performance and function requirements of electronic devices are continually increasing. Accordingly, higher-performance characteristics of semiconductor devices are increasingly desired, and the integration density of semiconductor devices is continually increasing to meet these industry demands. Various methods for forming semiconductor devices having improved performance and/or improved integration density are being studied.

### SUMMARY

Some example embodiments of the present disclosure provide a semiconductor device with improved electrical characteristics and/or reliability.

According to some example embodiments of the present disclosure, it may be possible to form the second source/drain contact by forming the contact spacer on the second source/drain pattern. Accordingly, the electrical characteristics and reliability of the semiconductor device may be improved.

According to some example embodiments of the present disclosure, a semiconductor device may include a substrate, a first channel pattern on the substrate, the first channel pattern having a first width in a first direction, a first gate electrode extending in a second direction on the first channel pattern, the second direction crossing the first direction, a first gate capping pattern on an upper surface of the first gate electrode, a second channel pattern spaced apart from the first channel pattern in the first direction, the first channel pattern having a second width in the first direction, a second gate electrode extending in the second direction on the second channel pattern, a second gate capping pattern on an upper surface of the second gate electrode, a source/drain pattern on at least one side of the second channel pattern, a first source/drain contact connected to the source/drain pattern, a second source/drain contact spaced apart from the first source/drain contact in the second direction, a contact isolation film between the first source/drain contact and the second source/drain contact, and a first contact spacer between the contact isolation film and the first source/drain contact. The second width is greater than the first width.

According to some example embodiments of the present disclosure, a semiconductor device may include a substrate, a first channel pattern on the substrate, the first channel pattern having a first width in a first direction, a second channel pattern spaced apart from the first channel pattern in the first direction, the second channel pattern having a second width in the first direction, a first source/drain pattern on at least one side of the first channel pattern, a first source/drain contact on the first source/drain pattern, a second source/drain pattern on at least one side of the second channel pattern, a second source/drain contact on the second source/drain pattern, a third source/drain contact spaced apart from the second source/drain contact in a second direction, the second direction crossing the first direction, a contact spacer surrounding a side surface of the second source/drain contact, and a first contact isolation film between the second source/drain contact and the third source/drain contact and in contact with the contact spacer. The second width is greater than the first width.

According to some example embodiments of the present disclosure, a semiconductor device may include a substrate, a first channel pattern on the substrate, the first channel pattern having a first width in a first direction, a first gate electrode extending in a second direction on the first channel pattern, the second direction crossing the first direction, a first gate capping pattern on an upper surface of the first gate electrode, a second channel pattern spaced apart from the first channel pattern in the first direction, the second channel pattern having a second width greater than the first width in the first direction, a second gate electrode extending in the second direction on the second channel pattern, a second gate capping pattern on an upper surface of the second gate electrode, a gate spacer on a side surface of the second gate electrode, a source/drain pattern on at least one side of the second channel pattern, a first source/drain contact on the source/drain pattern, a second source/drain contact spaced apart from the first source/drain contact in the second direction, a contact isolation film between the first source/drain contact and the second source/drain contact, and a contact spacer between the contact isolation film and the first source/drain contact. The contact spacer surrounds at least a portion of a side surface of the first source/drain contact, and at least a portion of the contact spacer is in contact with a side surface of the gate capping pattern.

According to some example embodiments of the present disclosure, a method of manufacturing a semiconductor device may include forming a fin-type pattern on a substrate, the fin-type pattern including a first channel pattern, a second channel pattern spaced apart from the first channel pattern, a first source/drain pattern on at least one side of the first channel pattern, a second source/drain pattern on at least one side of the second channel pattern, a first gate electrode stack on the first channel pattern, and a second gate electrode stack on the second channel pattern, forming a protective layer on the first source/drain pattern and at least a portion of the first gate electrode stack, forming a spacer liner on the protective layer, second source/drain pattern, and the second gate electrode stack, forming a mask layer on the protective layer, removing by a first etching process at least a portion of the mask layer, such that the mask layer remains above the second source/drain pattern and is removed above the first source/drain pattern, removing the mask layer remaining above the second source/drain pattern, at least a portion of the spacer liner, and the protective layer, forming by a second etching process a first trench and a second trench in the first source/drain pattern and the second source/drain pattern, respectively, forming a first source/drain contact in the first trench and a second source/drain contact in the second trench, and forming an upper wiring structure on the first gate electrode stack, the second gate electrode stack, the first source/drain contact, and the second source/drain contact.

According to some example embodiments of the present disclosure, the first channel pattern has a first width, the second channel pattern has a second width, and the second width is greater than the first width.

According to some example embodiments of the present disclosure, in the forming of the first trench and the second trench at least a portion of the first source/drain pattern is recessed to form the first trench, and at least a portion of the spacer liner and at least a portion of the second source/drain pattern are recessed to form the second trench.

According to some example embodiments of the present disclosure, the second etching process is performed using a mask patterned with a KrF or an ArF patterning process as an etching mask.

According to some example embodiments of the present disclosure, the first gate electrode stack includes a first gate electrode extending in a second direction on the first channel pattern, a first gate spacer on a side surface of the first gate electrode with a first gate insulating film therebetween, and a first gate capping pattern on the first gate electrode and the first gate spacer, and the second gate electrode stack includes a second gate electrode extending in a second direction on the first channel pattern, a second gate spacer on a side surface of the second gate electrode with a second gate insulating film therebetween, and a second gate capping pattern on the second gate electrode and the second gate spacer.

### BRIEF DESCRIPTION OF THE DRAWINGS

The above and other embodiments and features of the present disclosure will become more apparent by describing in detail example embodiments thereof with reference to the attached drawings, in which:

FIG. 1 is an example layout diagram provided to explain a semiconductor device according to some example embodiments;

FIG. 2 is a cross-sectional view taken along line A-A of FIG. 1;

FIG. 3 is a cross-sectional view taken along line B-B of FIG. 1;

FIG. 4 is a cross-sectional view taken along line C-C of FIG. 1;

FIG. 5 is a diagram provided to explain a semiconductor device according to some example embodiments;

FIGS. 6 and 7 are diagrams provided to explain a semiconductor device according to some example embodiments;

FIG. 8 is a diagram provided to explain a semiconductor device according to some example embodiments;

FIG. 9 is a diagram provided to explain a semiconductor device according to some example embodiments;

FIG. 10 is a diagram provided to explain a semiconductor device according to some example embodiments;

FIGS. 11 to 18 are diagrams provided to explain a method for manufacturing a semiconductor device according to some example embodiments.

### DETAILED DESCRIPTION

The terms such as first, second, etc. may be used herein to describe various devices or components, but the devices or components are not limited by these terms. It should be understood that these terms are only used to distinguish one element or component from another element or component. It goes without saying that the first element or component mentioned below may be the second element or component within the technical idea of the present disclosure.

A semiconductor device and a method for manufacturing the same according to some example embodiments of the present disclosure will be described in detail below with reference to the drawings.

In the drawings of the semiconductor device according to some example embodiments of the present disclosure, a fin-type transistor (FinFET) including a channel region of a fin-type pattern is illustrated as an example, but example embodiments are not limited thereto. The semiconductor device according to some example embodiments may include a tunneling transistor (tunneling FET), a transistor including a nanowire, a transistor including a nanosheet, or a three-dimensional (3D) transistor.

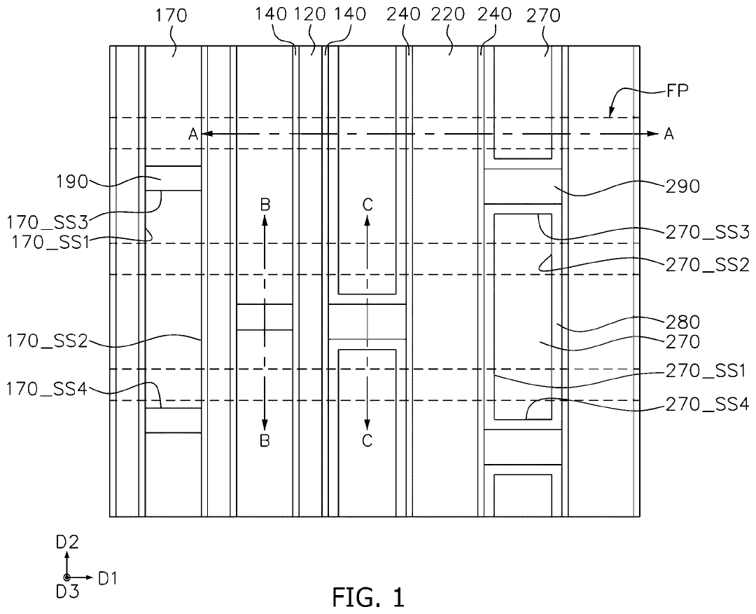

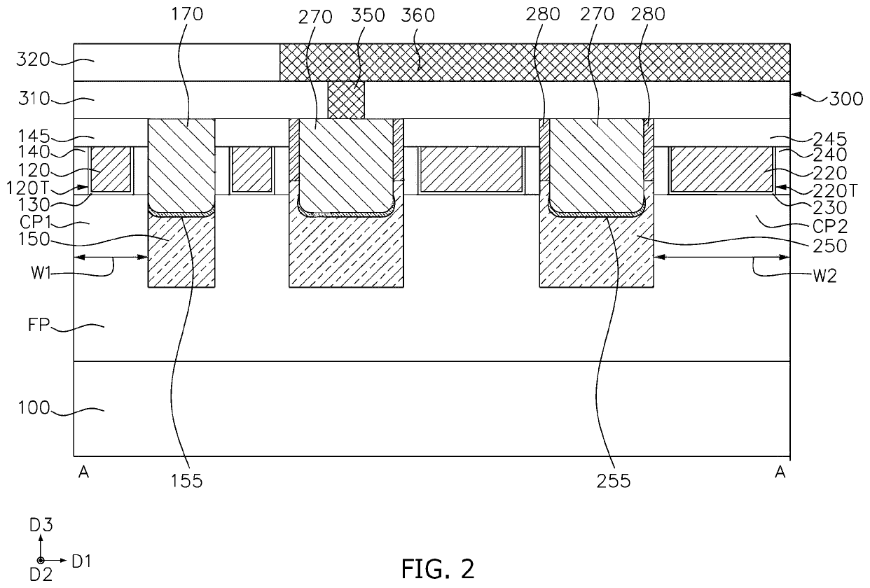

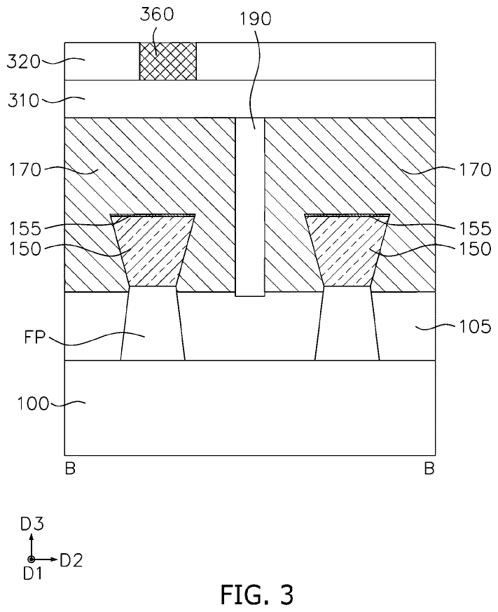

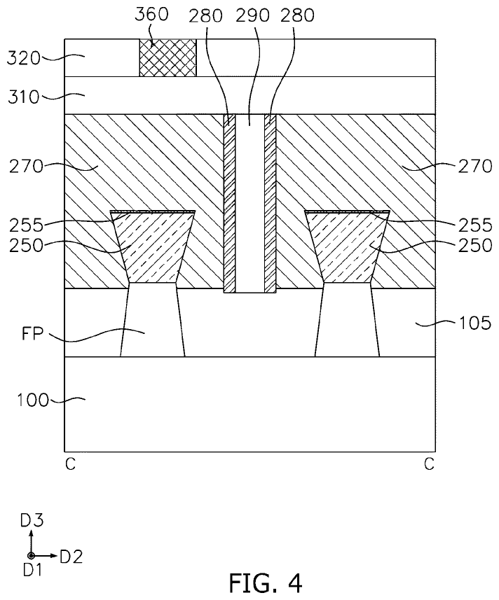

FIG. 1 is an example layout diagram provided to explain a semiconductor device according to some example embodiments. FIG. 2 is a cross-sectional view taken along line A-A of FIG. 1. FIG. 3 is a cross-sectional view taken along line B-B of FIG. 1. FIG. 4 is a cross-sectional view taken along line C-C of FIG. 1. For convenience of description, a first gate capping pattern 145, a second gate capping pattern 245, and an upper wiring structure 300 are omitted from the illustration of FIG. 1.

Referring to FIGS. 1 to 4, the semiconductor device according to some example embodiments may include a substrate 100, a first channel pattern CP1, a second channel pattern CP2, a first gate electrode 120, a second gate electrode 220, a first gate insulating film 130, a second gate insulating film 230, the first gate capping pattern 145, the second gate capping pattern 245, a first gate spacer 140, a second gate spacer 240, a first source/drain pattern 150, a second source/drain pattern 250, a first source/drain contact 170, a second source/drain contact 270, a first contact isolation film 190, a second contact isolation film 290, a contact spacer 280, the upper wiring structure 300, etc.

The substrate 100 may be a bulk silicon or a silicon-on-insulator (SOI). Alternatively, the substrate 100 may include silicon germanium (SiGe), silicon germanium on insulator (SGOI), indium antimony, lead telluride compound, indium arsenide, indium phosphide, gallium arsenide, or gallium antimony, but example embodiments are not limited thereto.

A fin-type pattern FP may protrude from the substrate 100. The fin-type pattern FP may extend in a first direction D1. The adjacent fin-type patterns FP may be disposed to be spaced apart from each other in a second direction D2. The first direction D1 may be a direction crossing the second direction D2, and for example, the first direction D1 may be perpendicular to the second direction D2. Each of the first and second directions D1 and D2 may be a direction parallel to an upper surface of the substrate 100.

The fin-type pattern FP may be a portion of the substrate 100 and may include an epitaxial layer grown from the substrate 100. For example, the fin-type pattern FP may include an element semiconductor material such as silicon or germanium. In addition, the fin-type pattern FP may include a compound semiconductor, for example, a group IV-IV compound semiconductor or a group III-V compound semiconductor. Specifically, for examples of group IV-IV compound semiconductors, each fin-type pattern FP may include a binary compound or a ternary compound including at least two or more of carbon (C), silicon (Si), germanium (Ge), and tin (Sn), or these compounds doped with a group IV element. For examples of group III-IV compound semiconductors, each fin-type pattern FP may include one of a binary compound, a ternary compound, or a quaternary compound formed by the combination of at least one group III element such as aluminum (Al), gallium (Ga), and indium (In) with one group V element such as phosphorus (P), arsenic (As), and antimony (Sb). However, example embodiments are not limited thereto.

A field insulating film 105 may be formed on the substrate 100. The field insulating film 105 may cover a portion of the fin-type pattern FP. For example, the field insulating film 105 may be disposed on a portion of the sidewall of the fin-type pattern FP. An upper surface of the fin-type pattern FP may protrude upward further than an upper surface of the field insulating film 105. The fin-type pattern FP may be defined by the field insulating film 105 on the substrate 100. For example, the field insulating film 105 may include at least one of a silicon oxide film, a silicon nitride film, and a silicon oxynitride film.

The fin-type pattern FP may include the first channel pattern CP1 and the second channel pattern CP2. The first channel pattern CP1 and the second channel pattern CP2 may be disposed to be spaced apart from each other in the first direction D1. The first channel pattern CP1 may have a first width W1 in the first direction D1. The second channel pattern CP2 may have a second width W2 in the first direction D1. The second width W2 may be greater than the first width W1.

The first gate electrode 120 may extend on the fin-type pattern FP and the field insulating film 105 in the second direction D2. The first gate electrode 120 may intersect with the fin-type pattern FP. The first gate electrode 120 may be disposed on the first channel pattern CP1 of the fin-type pattern FP. The first gate electrode 120 may surround three surfaces of the first channel pattern CP1. For example, the first gate electrode 120 may be disposed on an upper surface and both side surfaces of the first channel pattern CP1.

The second gate electrode 220 may extend in the second direction D2 on the fin-type pattern FP and the field insulating film 105. The second gate electrode 220 may intersect with the fin-type pattern FP. The second gate electrode 220 may be disposed on the second channel pattern CP2 of the fin-type pattern FP. The second gate electrode 120 may surround three surfaces of the second channel pattern CP2. For example, the second gate electrode 120 may be disposed on an upper surface and both side surfaces of the second channel pattern CP2.

The second gate electrode 220 may be disposed to be spaced apart from the first gate electrode 120 in the first direction D1. A width of the second gate electrode 220 in the first direction D1 may be greater than a width of the first gate electrode 120 in the first direction D1.

Each of the first gate electrode 120 and the second gate electrode 220 may include at least one of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination of these. However, example embodiments are not limited thereto.

The first gate insulating film 130 may be disposed on a first gate trench 120T. The first gate insulating film 130 may extend along a side surface and a bottom surface of the first gate trench 120T. The first gate insulating film 130 may be disposed between the first gate electrode 120 and the first channel pattern CP1. The first gate electrode 120 may be disposed on the first gate insulating film 130. The first gate electrode 120 may fill the remaining portion of the first gate trench 120T that is not occupied by the first gate insulating film 130.

The second gate insulating film 230 may be disposed on a second gate trench 220T. The second gate insulating film 230 may extend along a side surface and a bottom surface of the second gate trench 220T. The second gate insulating film 230 may be disposed between the second gate electrode 220 and the second channel pattern CP2. The second gate electrode 220 may be disposed on the second gate insulating film 230. The second gate electrode 220 may fill the remaining portion of the second gate trench 220T that is not occupied by the second gate insulating film 230.

In some example embodiments, each of the first gate insulating film 130 and the second gate insulating film 230 may include a high-k insulating film. The high-k insulating film may include a high-k material having a higher dielectric constant than the silicon oxide film. Each of the first and second gate insulating films 130 and 230 may include at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate. However, example embodiments are not limited thereto.

The first gate spacers 140 may be disposed on both sidewalls of the first gate electrode 120. The first gate spacer 140 may extend along a sidewall of the first gate electrode 120 in the second direction D2.

The first gate capping pattern 145 may be disposed on an upper surface of the first gate electrode 120 and an upper surface of the first gate spacer 140. The first gate capping pattern 145 may cover the upper surface of the first gate electrode 120. The first gate capping pattern 145 may overlap with the first gate electrode 120 in a third direction D3.

Although the first gate capping pattern 145 is illustrated as being disposed on the upper surface of the first gate spacer 140, example embodiments are not limited thereto. For example, the first gate spacers 140 may protrude further than the upper surface of the first gate electrode 120 such that a portion of the first gate capping pattern 145 may be disposed between the first gate spacers 140. In some example embodiments, a boundary surface between the first gate capping pattern 145 and the first gate spacer 140 may not be distinguished.

The second gate spacers 240 may be disposed on both sidewalls of the second gate electrode 220. The second gate spacer 240 may extend along a sidewall of the second gate electrode 220 in the second direction D2.

The second gate capping pattern 245 may be disposed on an upper surface of the second gate electrode 220 and an upper surface of the second gate spacer 240. The second gate capping pattern 245 may cover the upper surface of the second gate electrode 220. The second gate capping pattern 245 may overlap with the second gate electrode 220 in the third direction D3.

Although the second gate capping pattern 245 is illustrated as being disposed on the upper surface of the second gate spacer 240, example embodiments are not limited thereto. For example, the second gate spacers 240 may protrude further than the upper surface of the second gate electrode 220 such that a portion of the second gate capping pattern 245 may be disposed between the second gate spacers 240. In some example embodiments, a boundary surface between the second gate capping pattern 245 and the second gate spacer 240 may not be distinguished.

For example, each of the first gate spacer 140 and the second gate spacer 240 may include at least one of silicon nitride (SiN), silicon nitride oxide (SiON), silicon oxide (SiO—), silicon carbonate nitride (SiOCN), silicon boron nitride (SiBN), silicon oxide boron nitride (SiOBN), silicon oxide carbonate (SiOC), or a combination of these. Although each of the first gate spacer 140 and the second gate spacer 240 is illustrated as a single film, this is only for convenience of description, and example embodiments are not limited thereto.

For example, each of the first gate capping pattern 145 and the second gate capping pattern 245 may include at least one of silicon nitride (SiN), silicon oxynitride (SiON), silicon carbonitride (SiCN), silicon oxycarbonitride (SiOCN), or a combination of these. However, example embodiments are not limited thereto.

The first source/drain pattern 150 may be disposed on the fin-type pattern FP. The first source/drain pattern 150 may be disposed on at least one side of the first channel pattern CP1. The first source/drain pattern 150 may be in contact with the first channel pattern CP1. The first source/drain pattern 150 may serve as a source/drain of a transistor that uses the first channel pattern CP1 as a channel region.

The second source/drain pattern 250 may be disposed on the fin-type pattern FP. The second source/drain pattern 250 may be disposed on at least one side of the second channel pattern CP2. The second source/drain pattern 250 may be in contact with the second channel pattern CP2. The second source/drain pattern 250 may serve as a source/drain of a transistor that uses the second channel pattern CP2 as a channel region.

Each of the first source/drain pattern 150 and the second source/drain pattern 250 may include a semiconductor material. For example, the first source/drain pattern 150 may include an element semiconductor material such as silicon (Si) or germanium (Ge). In addition, for example, the first source and drain pattern 150 may include a binary compound or a ternary compound including at least two or more of carbon (C), silicon (Si), germanium (Ge), tin (Sn), or these compounds doped with a group IV element. For example, the first source/drain pattern 150 may include silicon (Si), silicon-germanium (SiGe), germanium (Ge), silicon carbide (SiC), etc., but example embodiments are not limited thereto.

Although each of the first source/drain pattern 150 and the second source/drain pattern 250 is illustrated as a single film, this is only for convenience of description, and example embodiments are not limited thereto. Each of the first source/drain pattern 150 and the second source/drain pattern 250 may include a plurality of films including different materials. In another aspect, each of the first source/drain pattern 150 and the second source/drain pattern 250 may include the same material, and may include a plurality of layers having different concentrations of the constituent material.

A first silicide film 155 may be disposed on an upper surface of the first source/drain pattern 150. The first silicide film 155 may be disposed between the first source/drain pattern 150 and the first source/drain contact 170. A second silicide film 255 may be disposed on an upper surface of the second source/drain pattern 250. The second silicide film 255 may be disposed between the second source/drain pattern 250 and the second source/drain contact 270.

The first source/drain contact 170 and the second source/drain contact 270 will be described in detail below.

The first source/drain contact 170 may be disposed on the first source/drain pattern 150. The first source/drain contact 170 may be in contact with the first silicide film 155. The first source/drain contact 170 may be electrically connected to the first source/drain pattern 150.

The first source/drain contact 170 may extend in the second direction D2. The first gate electrode 120 may be disposed between the first source/drain contacts 170 adjacent to each other in the first direction D1. The first contact isolation film 190 may be disposed between the first source/drain contacts 170 adjacent to each other in the second direction D2. The first source/drain contacts 170 adjacent to each other in the second direction D2 may overlap with each other in the second direction D2.

The first source/drain contact 170 may be in contact with the first contact isolation film 190, the first gate capping pattern 145, and the first gate spacer 140. The first source/drain contact 170 may include first to fourth side surfaces 170_SS1, 170_SS2, 170_SS3, and 170_SS4. The first side surface 170_SS1 and the second side surface 170_SS2 of the first source/drain contact 170 may face each other in the first direction D1, and the third side surface 170_SS3 and the fourth side surface 170_SS4 of the first source/drain contact 170 may face each other in the second direction D2. The first side surface 170_SS1 and the second side surface 170_SS2 of the first source/drain contact 170 may be in contact with the first gate spacer 140 and the first gate capping pattern 145. The third side surface 170_SS3 and the fourth side surface 170_SS4 of the first source/drain contact 170 may be in contact with the first contact isolation film 190.

The second source/drain contact 270 may be disposed on the second source/drain pattern 250. The second source/drain contact 270 may be in contact with the second silicide film 255. The second source/drain contact 270 may be electrically connected to the second source/drain pattern 250.

The second source/drain contact 270 may extend in the second direction D2. The second gate electrode 220 may be disposed between the second source/drain contacts 270 adjacent to each other in the first direction D1. The second contact isolation film 290 may be disposed between the second source/drain contacts 270 adjacent to each other in the second direction D2. The second source/drain contacts 270 adjacent to each other in the second direction D2 may overlap with each other in the second direction D2.

The second source/drain contact 270 may be disposed on a side surface of the contact spacer 280. The contact spacer 280 may be disposed around the second source/drain contact 270. The contact spacer 280 may surround at least a portion of a side surface of the second source/drain contact 270.

The contact spacer 280 may be in contact with the side surface of the second source/drain contact 270. The second source/drain contact 270 may include first to fourth side surfaces 270_SS1, 270_SS2, 270_SS3, and 270_SS4. The first side surface 270_SS1 and the second side surface 270_SS2 of the second source/drain contact 270 may face each other in the first direction D1, and the third side surface 270_SS3 and the fourth side surface 270_SS4 of the second source/drain contact 270 may face each other in the second direction D2. The contact spacer 280 may be in contact with each of the first to fourth side surfaces 270_SS1, 270_SS2, 270_SS3, and 270_SS4 of the second source/drain contact 270.

The contact spacer 280 may be disposed on side surfaces of the second gate capping pattern 245 and the second gate spacer 240. The contact spacer 280 may be in contact with the second gate capping pattern 245 and the second gate spacer 240. The contact spacer 280 may be disposed between the second source/drain contact 270 and the second gate capping pattern 245 and between the second source/drain contact 270 and the second gate spacer 240.

In some example embodiments, a distance from the upper surface of the substrate 100 to an upper surface of the second source/drain contact 270 may be the same as a distance from the upper surface of the substrate 100 to an upper surface of the contact spacer 280. However, example embodiments are not limited thereto. The upper surface of the second source/drain contact 270 may be a surface in contact with a first upper insulating film 310, and the upper surface of the contact spacer 280 may be a surface in contact with the first upper insulating film 310.

In some example embodiments, the contact spacer 280 may be in contact with the second source/drain pattern 250. For example, a bottom surface of the contact spacer 280 may be in contact with the second source/drain pattern 250.

A width of the first source/drain contact 170 in the first direction D1 may be the same as a width of the first contact isolation film 190 in the first direction D1. A width of the second source/drain contact 270 in the first direction D1 may be less than a width of the second contact isolation film 290 in the first direction D1. The width of the second contact isolation film 290 in the first direction D1 may be the same as the width of the contact spacer 280 in the first direction D1.

Each of the first source/drain contact 170 and the second source/drain contact 270 may include a conductive material. For example, each of the first source/drain contact 170 and the second source/drain contact 270 may include at least one of a metal, a metal alloy, a conductive metal nitride, a conductive metal carbide, a conductive metal oxide, a conductive metal carbonitride, and a two-dimensional material. However, example embodiments are not limited thereto.

Although each of the first source/drain contact 170 and the second source/drain contact 270 is illustrated herein as a single film, example embodiments are not limited thereto. For example, each of the first source/drain contact 170 and the second source/drain contact 270 may include a conductive barrier film and a conductive filling film disposed on the barrier film.

Each of the first contact isolation film 190 and the second contact isolation film 290 may include an insulating material. For example, each of the first contact isolation film 190 and the second contact isolation film 290 may include at least one of silicon nitride (SiN), silicon oxynitride (SiON), silicon carbonitride (SiCN), silicon oxycarbonitride (SiOCN), or a combination of these. However, example embodiments are not limited thereto.

The contact spacer 280 may include an insulating material. In some example embodiments, the contact spacer 280 may include a material different from that of the second contact isolation film 290. For example, the contact spacer 280 may include at least one of silicon oxide (SiO), silicon nitride (SiN), silicon oxynitride (SiON), or a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination of these, but example embodiments are not limited thereto.

The upper wiring structure 300 may be disposed on the first gate capping pattern 145, the first source/drain contact 170, the second gate capping pattern 245, and the second source/drain contact 270. The upper wiring structure 300 may include the first upper insulating film 310, a second upper insulating film 320, a first wiring layer 350, and a second wiring layer 360.

The first upper insulating film 310 may be disposed on an upper surface of the first source/drain contact 170 and the upper surface of the second source/drain contact 270. The first wiring layer 350 may be disposed within the first upper insulating film 310. The first wiring layer 350 may be electrically connected to the second source/drain contact 270.

The second upper insulating film 320 may be disposed on the first upper insulating film 310. The second wiring layer 360 may be disposed within the second upper insulating film 320. The second wiring layer 360 may be disposed on the first wiring layer 350. The second wiring layer 360 may be electrically connected to the first wiring layer 350. The second wiring layer 360 may extend in the first direction D1.

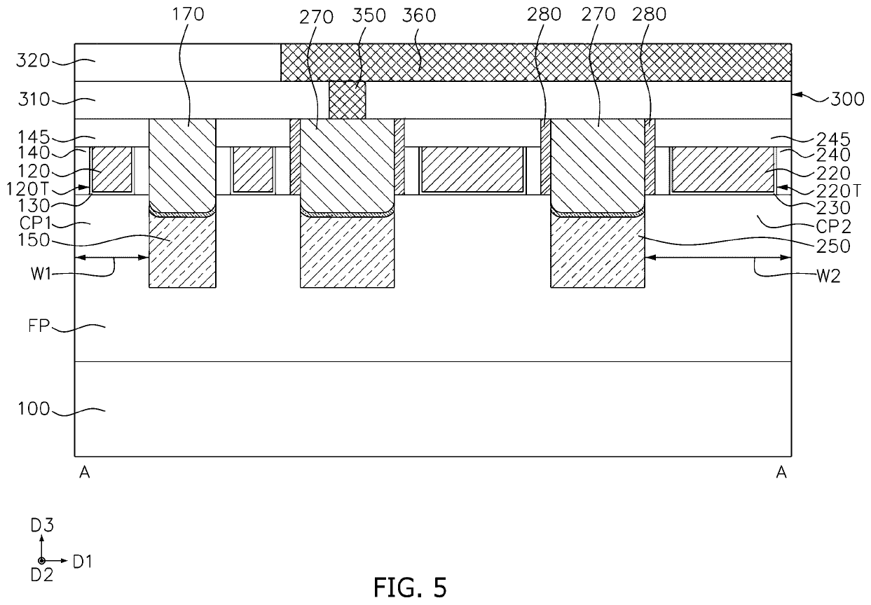

FIG. 5 is a diagram provided to explain a semiconductor device according to some example embodiments. For convenience of description, differences from the configurations described above in FIGS. 1 to 4 will be mainly described.

Referring to FIG. 5, in the semiconductor device according to some example embodiments, the contact spacer 280 may be disposed on the fin-type pattern FP.

The contact spacer 280 may be disposed on the second channel pattern CP2 of the fin-type pattern FP. The bottom surface of the contact spacer 280 may be in contact with an upper surface of the second channel pattern CP2. The bottom surface of the contact spacer 280 may be disposed on the same plane as a bottom surface of the second gate electrode 220. By forming the contact spacer 280 on the second channel pattern CP2, and surrounding at least a portion of a side surface the second source/drain contact 270, the electrical characteristics and/or reliability of the semiconductor device may be improved.

In some example embodiments, the width of the second source/drain contact 270 in the first direction D1 may be the same as the width of the second source/drain pattern 250 in the first direction D1.

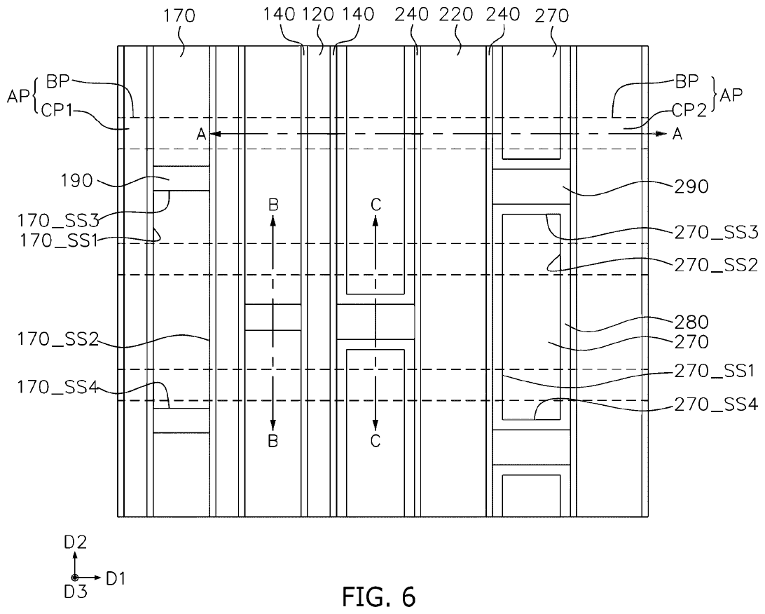

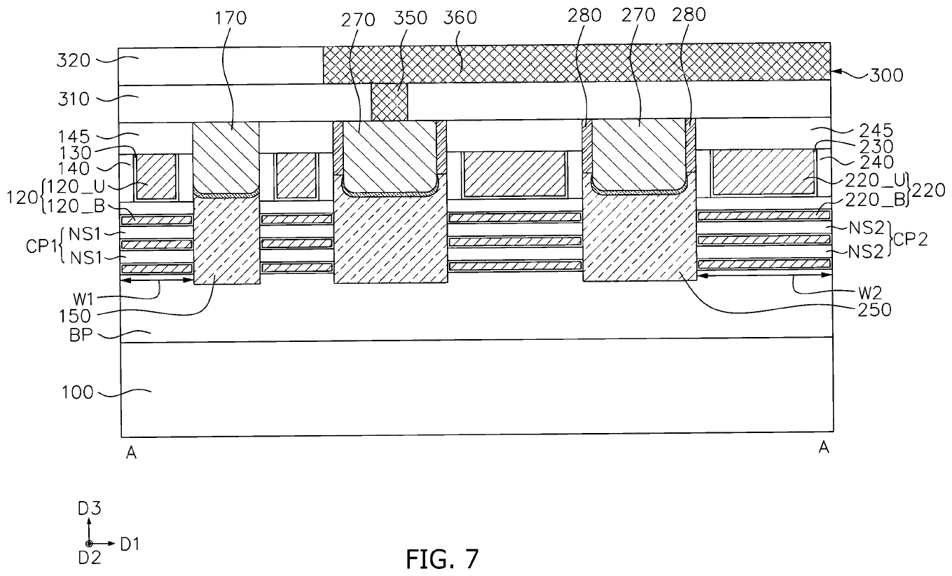

FIGS. 6 and 7 are diagrams provided to explain a semiconductor device according to some example embodiments. For convenience of description, differences from the configurations described above in FIGS. 1 to 4 will be mainly described.

The semiconductor device according to some example embodiments may include a MOSFET, and more specifically, may include a gate-all-round (GAA) transistor and a three-dimensional multi-stack semiconductor device referred to as a multi-bridge channel FET (MBCFET).

Referring to FIGS. 6 and 7, the semiconductor device according to some example embodiments may include the substrate 100, an active pattern AP, the first gate electrode 120, the second gate electrode 220, the first gate insulating film 130, the second gate insulating film 230, the first gate capping pattern 145, the second gate capping pattern 245, the first gate spacer 140, the second gate spacer 240, the first source/drain pattern 150, the second source/drain pattern 250, the first source/drain contact 170, the second source/drain contact 270, the first contact isolation film 190, the second contact isolation film 290, the contact spacer 280, the upper wiring structure 300, etc.

The substrate 100 may be a bulk silicon or a silicon-on-insulator (SOI). Alternatively, the substrate 100 may include silicon germanium (SiGe), silicon germanium on insulator (SGOI), indium antimony, lead telluride compound, indium arsenide, indium phosphide, gallium arsenide, or gallium antimony, but example embodiments are not limited thereto.

The active pattern AP may be disposed on the substrate 100. The active pattern AP may extend in the first direction D1. The active pattern AP may be disposed to be spaced apart from the adjacent active pattern AP in the second direction D2.

The active pattern AP may be a multi-channel active pattern. The active pattern AP may include a lower pattern BP, the first channel pattern CP1, and the second channel pattern CP2.

The lower pattern BP may protrude from the substrate 100. The lower pattern BP may extend in the first direction D1. The lower pattern BP may be spaced apart from the adjacent lower pattern BP in the second direction D2. The adjacent lower patterns BP may be separated by a field trench. The field trench may be defined by the upper surface of the substrate 100 and the side surfaces of the lower pattern BP.

The first channel pattern CP1 may be disposed on the lower pattern BP. The first channel pattern CP1 may include a plurality of first sheet patterns NS1. The plurality of first sheet patterns NS1 may be spaced apart from the lower pattern BP in the third direction D3. Each of the first sheet patterns NS1 may be spaced apart in the third direction D3. The third direction D3 may be a thickness direction of the substrate 100. The first sheet pattern NS1 may have a nanosheet shape. Although it is illustrated that there are three first sheet patterns NS1, example embodiments are not limited thereto.

The second channel pattern CP2 may be disposed on the lower pattern BP. The second channel pattern CP2 may include a plurality of second sheet patterns NS2. The plurality of second sheet patterns NS2 may be spaced apart from the lower pattern BP in the third direction D3. Each of the second sheet patterns NS2 may be spaced apart in the third direction D3. The third direction D3 may be a thickness direction of a substrate 200. The second sheet pattern NS2 may have a nanosheet shape. Although it is illustrated that there are three second sheet patterns NS2, example embodiments are not limited thereto.

The first channel pattern CP1 may have the first width W1 in the first direction D1. The first width W1 may be the same as a width of the first sheet pattern NS1 in the first direction D1. The second channel pattern CP2 may have the second width W2 in the first direction D1. The second width W2 may be the same as a width of the second sheet pattern NS2 in the first direction D1. The second width W2 may be greater than the first width W1.

The lower pattern BP may be formed by etching a portion of the substrate 100. However, example embodiments are not limited thereto. For example, the lower pattern BP may include an epitaxial layer grown from the substrate 100. The lower pattern BP may include an element semiconductor material such as silicon (Si) or germanium (Ge). In addition, the lower pattern BP may include a compound semiconductor. For example, the lower pattern BP may include a group IV-IV compound semiconductor or a group III-V compound semiconductor.

For example, the group IV-IV compound semiconductor may be a binary compound or a ternary compound including at least two of carbon (C), silicon (Si), germanium (Ge), and tin (Sn). However, example embodiments are not limited thereto.

For example, the group III-V compound semiconductor may be one of a binary compound, a ternary compound, or a quaternary compound formed by a combination of at least one group III element, such as aluminum (Al), gallium (Ga), and indium (In) with one of group V element, such as phosphorus (P), arsenic (As), and antimony (Sb). However, example embodiments are not limited thereto.

Each of the first sheet pattern NS1 and the second sheet pattern NS2 may include one of an element semiconductor material such as silicon (Si) or silicon germanium (SiGe), a group IV-IV compound semiconductor, or a group III-V compound semiconductor. Each of the first sheet pattern NS1 and the second sheet pattern NS2 may include the same material as the lower pattern BP, or may include a different material from the lower pattern BP.

Each of the lower pattern BP, the first sheet pattern NS1, and the second sheet pattern NS2 may include silicon (Si). In another aspect, each of the lower pattern BP, the first sheet pattern NS1, and the second sheet pattern NS2 may include silicon germanium (SiGe). In another aspect, the lower pattern BP may include silicon (Si), and each of the first sheet pattern NS1 and the second sheet pattern NS2 may include silicon germanium (SiGe).

The first field insulating film 105 may be disposed on the substrate 100. The first field insulating film 105 may fill a portion of the field trench. The first field insulating film 105 may be disposed between the adjacent lower patterns BP. The first field insulating film 105 may extend in the first direction D1. The first field insulating film 105 may be formed on the upper surface of the substrate 100. The first field insulating film 105 may cover a portion of the sidewall of the lower pattern BP.

For example, the first field insulating film 105 may include oxide, nitride, nitride oxide, or a combination of these. Although it is illustrated that the first field insulating film 105 is a single film, this is only for convenience of description, and example embodiments are not limited thereto. For example, the first field insulating film 105 may be formed of a plurality of films.

The first gate electrode 120 may extend on the substrate 100 in the second direction D2. The first gate electrode 120 may intersect with the active pattern AP. The first gate electrode 120 may be disposed on the lower pattern BP. The adjacent first gate electrodes 120 may be disposed to be spaced apart from each other in the first direction D1. The first gate electrode 120 may be disposed on the first channel pattern CP1. The first gate electrode 120 may surround the plurality of first sheet patterns NS1. The first gate electrode 120 may surround four surfaces of the first sheet pattern NS1. For example, the first gate electrode 120 may surround an upper surface, a lower surface, and both side surfaces of the first sheet pattern NS1. The upper and lower surfaces of the first sheet pattern NS1 may face each other in the third direction D3, and both side surfaces of the first sheet pattern NS1 may face each other in the second direction D2.

The first gate electrode 120 may include a first upper gate electrode 120_U and a first lower gate electrode 120_B. The first lower gate electrode 120_B may be disposed between the first sheet patterns NS1 adjacent to each other in the third direction D3. The first lower gate electrode 120_B may be disposed among the plurality of first sheet patterns NS1, and also between the lower pattern BP and the lowermost first sheet pattern NS1 in the plurality of first sheet patterns NS1. The first upper gate electrode 120_U may be disposed on the uppermost first sheet pattern NS1 in the plurality of first sheet patterns NS1.

The second gate electrode 220 may extend on the substrate 100 in the second direction D2. The second gate electrode 220 may intersect with the active pattern AP. The second gate electrode 220 may be disposed on the lower pattern BP. The second gate electrode 220 may be disposed to be spaced apart from the adjacent second gate electrode 220 in the first direction D1. The second gate electrode 220 may be disposed on the second channel pattern CP2. The second gate electrode 220 may surround the plurality of second sheet patterns NS2. The second gate electrode 220 may surround four surfaces of the second sheet pattern NS2. For example, the second gate electrode 220 may surround an upper surface, a lower surface, and both side surfaces of the second sheet pattern NS2. The upper and lower surfaces of the second sheet pattern NS2 may face each other in the third direction D3, and both side surfaces of the second sheet pattern NS2 may face each other in the second direction D2.

The second gate electrode 220 may include a second upper gate electrode 220_U and a second lower gate electrode 220_B. The second lower gate electrode 220_B may be disposed between the second sheet patterns NS2 adjacent to each other in the third direction D3. The second lower gate electrode 220_B may be disposed among the plurality of second sheet patterns NS2, and may also be disposed between the lower pattern BP and the lowermost second sheet pattern NS2 in the plurality of second sheet patterns NS2. The second upper gate electrode 220_U may be disposed on the uppermost second sheet pattern NS2 in the plurality of second sheet patterns NS2.

The first gate insulating film 130 may be disposed between the first gate electrode 120 and the plurality of first sheet patterns NS1, between the first gate electrode 120 and the lower pattern BP, and between the first gate electrode 120 and the first source/drain pattern 150. Specifically, the first gate insulating film 130 may be disposed between the first upper gate electrode 120_U and the uppermost first sheet pattern NS1 in the plurality of first sheet patterns NS1. The first gate insulating film 130 may be disposed between the first lower gate electrode 120_B and the first sheet pattern NS1. The first gate insulating film 130 may surround the first sheet pattern NS1. The first gate insulating film 130 may extend in the first direction D1 along the upper and lower surfaces of the first sheet pattern NS1.

The second gate insulating film 230 may be disposed between the second gate electrode 220 and the plurality of second sheet patterns NS2, between the second gate electrode 220 and the lower pattern BP, and between the second gate electrode 220 and the second source/drain pattern 250. Specifically, the second gate insulating film 230 may be disposed between the second upper gate electrode 220_U and the uppermost second sheet pattern NS2 in the plurality of second sheet patterns NS2. The second gate insulating film 230 may be disposed between the second lower gate electrode 220_B and the second sheet pattern NS2. The second gate insulating film 230 may surround the second sheet pattern NS2. The second gate insulating film 230 may extend in the first direction D1 along the upper and lower surfaces of the second sheet pattern NS2.

Descriptions of the first gate spacer 140, the first gate capping pattern 145, the first source/drain pattern 150, the first source/drain contact 170, and the first contact isolation film 190 may be the same as those described above with reference to FIGS. 1 to 4. In addition, descriptions of the second gate spacer 240, the second gate capping pattern 245, the second source/drain pattern 250, the second source/drain contact 270, the second contact isolation film 290, and the contact spacer 280 may be the same as those described above with reference to FIGS. 1 to 4.

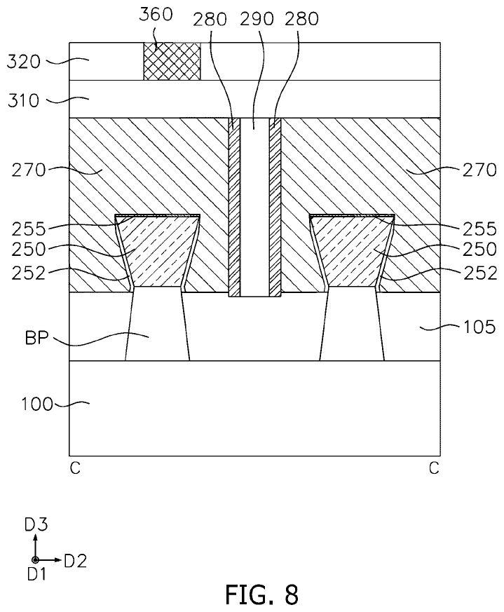

FIG. 8 is a diagram provided to explain a semiconductor device according to some example embodiments. For convenience of description, differences from the configurations described above in FIGS. 1 to 4 will be mainly described. For reference, FIG. 8 may correspond to a cross-sectional view taken along line C-C of FIG. 1.

Referring to FIG. 8, the semiconductor device according to some example embodiments may further include an etch stop film 252.

The etch stop film 252 may be disposed on the second source/drain pattern 250. The etch stop film 252 may be disposed on both side surfaces of the second source/drain pattern 250. For example, the etch stop film 252 may be disposed between a side surface of the second source/drain pattern 250 and the second source/drain contact 270.

In some example embodiments, the etch stop film 252 may not be disposed on the upper surface of the second source/drain pattern 250. That is, the upper surface of the second source/drain pattern 250 may be in contact with the second source/drain contact 270. The etch stop film 252 may be a portion that remains unremoved in the etching process for forming the second source/drain contact 270.

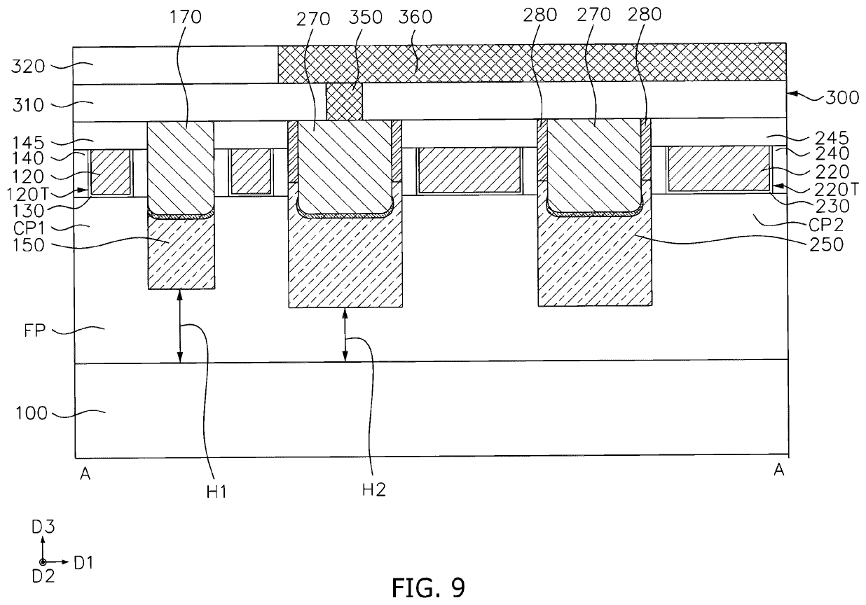

FIG. 9 is a diagram provided to explain a semiconductor device according to some example embodiments. For convenience of description, differences from the configurations described above in FIGS. 1 to 4 will be mainly described.

Referring to FIG. 9, in the semiconductor device according to some example embodiments, a depth of the first source/drain pattern 150 may be different from a depth of the second source/drain pattern 250.

A height from the upper surface of the substrate 100 to a bottom surface of the first source/drain pattern 150 may be a first distance H1. A height from the upper surface of the substrate 100 to a bottom surface of the second source/drain pattern 250 may be a second distance H2. The first distance H1 and the second distance H2 may be distances in the third direction D3. The first distance H1 may be greater than the second distance H2. In other words, the depth of the first source/drain pattern 150 may be less than the depth of the second source/drain pattern 250.

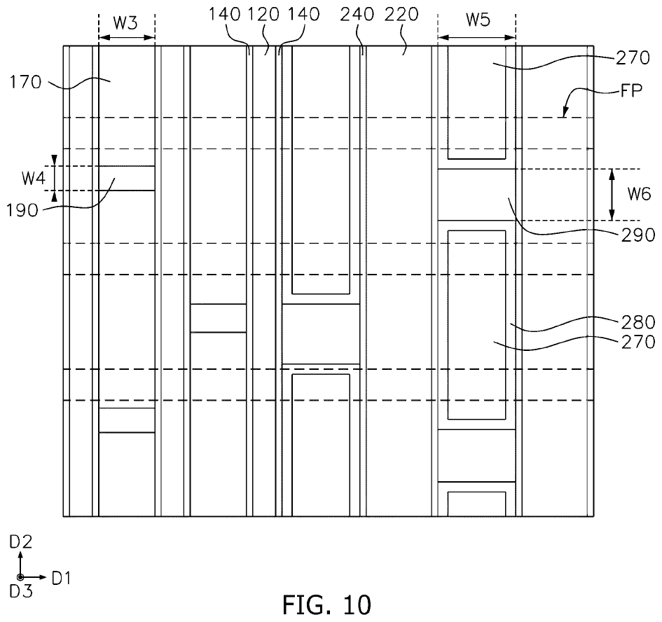

FIG. 10 is a diagram provided to explain a semiconductor device according to some example embodiments. For convenience of description, differences from the configurations described above in FIGS. 1 to 4 will be mainly described.

Referring to FIG. 10, in the semiconductor device according to some example embodiments, the width of the first contact isolation film 190 may be different from the width of the second contact isolation film 290.

The first contact isolation film 190 may have a third width W3 in the first direction D1, and may have a fourth width W4 in the second direction D2. The second contact isolation film 290 may have a fifth width W5 in the first direction D1, and may have a sixth width W6 in the second direction D2. The fifth width W5 may be equal to or substantially equal to or greater than the third width W3. The sixth width W6 may be equal to or substantially equal to or greater than the fourth width W4.

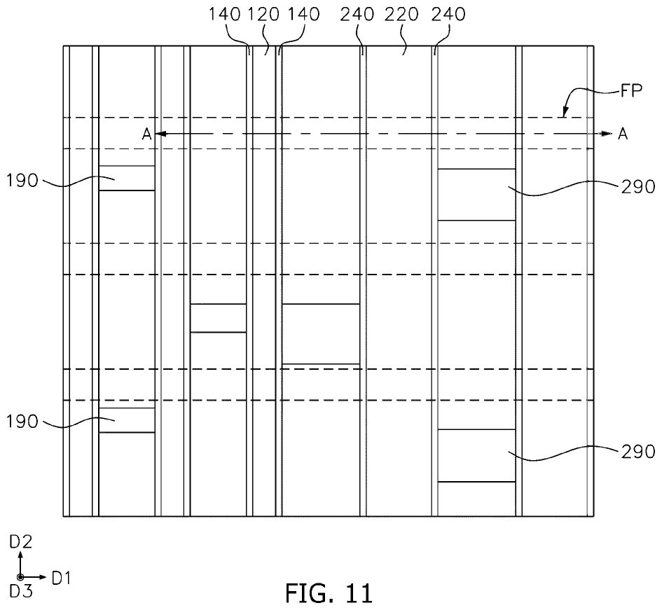

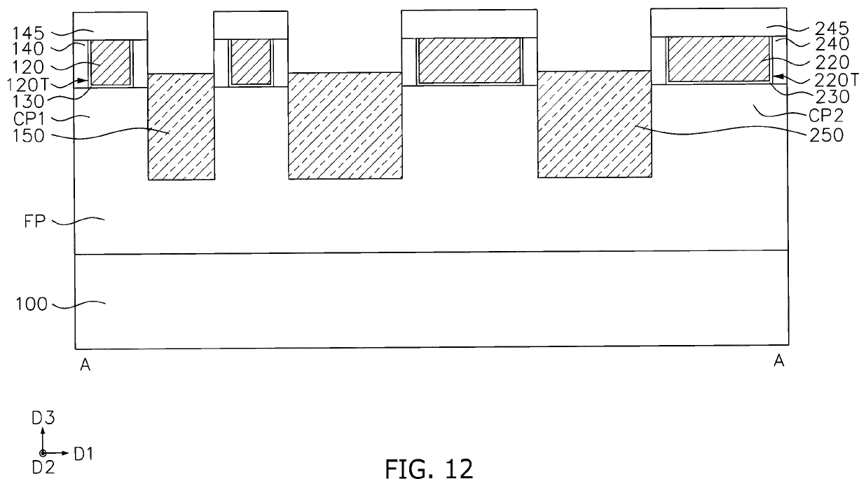

FIGS. 11 to 18 are diagrams provided to explain a method for manufacturing a semiconductor device according to some example embodiments. For reference, FIG. 11 is a cross-sectional view provided to explain a method for manufacturing a semiconductor device according to some example embodiments, and FIGS. 12 to 18 are cross-sectional views taken along line A-A of FIG. 11.

Referring to FIGS. 11 and 12, the fin-type pattern FP, the first gate electrode 120, the second gate electrode 220, the first gate spacer 140, the second gate spacer 240, the first gate capping pattern 145, the second gate capping pattern 245, the first source/drain pattern 150, and the second source/drain pattern 250 may be formed on the substrate 100.

The fin-type pattern FP may include the first channel pattern CP1 and the second channel pattern CP2. A width of the first channel pattern CP1 in the first direction D1 may be less than a width of the second channel pattern CP2 in the first direction D1.

In some example embodiments, the upper surface of the first source/drain pattern 150 may be disposed at a higher level than a lower surface of the first gate electrode 120. A portion of the first source/drain pattern 150 may be disposed on the first gate spacer 140. The upper surface of the second source/drain pattern 250 may be disposed at a higher level than a lower surface of the second gate electrode 220. A portion of the second source/drain pattern 250 may be disposed on the second gate spacer 240.

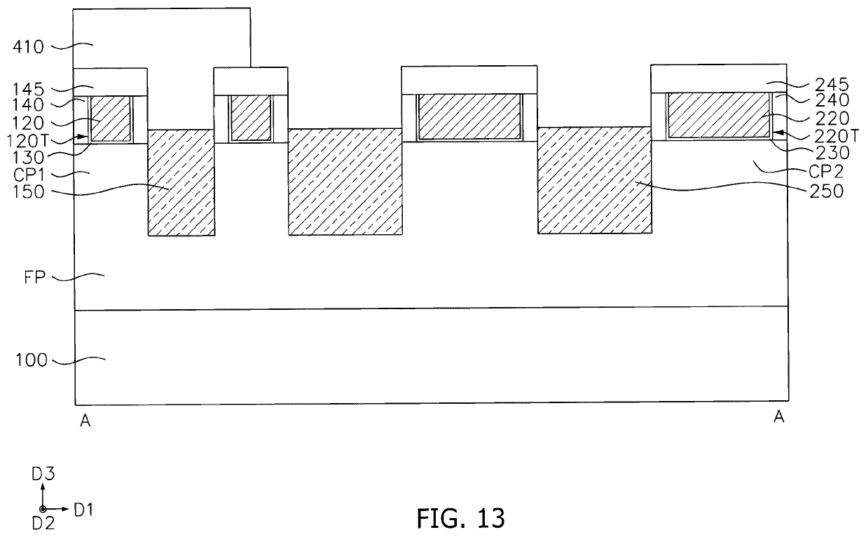

Referring to FIG. 13, a protective layer 410 may be formed on the first source/drain pattern 150 and the first gate capping pattern 145. The protective layer 410 may completely cover the upper surface of the first source/drain pattern 150. The first source/drain pattern 150 may be protected in subsequent processes by the protective layer 410. The protective layer 410 may be formed on an upper surface of the first gate capping pattern 145. Although the protective layer 410 is shown to expose a portion of the upper surface of the first gate capping pattern 145, example embodiments are not limited thereto. For example, the protective layer 410 may completely cover the upper surface of the first gate capping pattern 145.

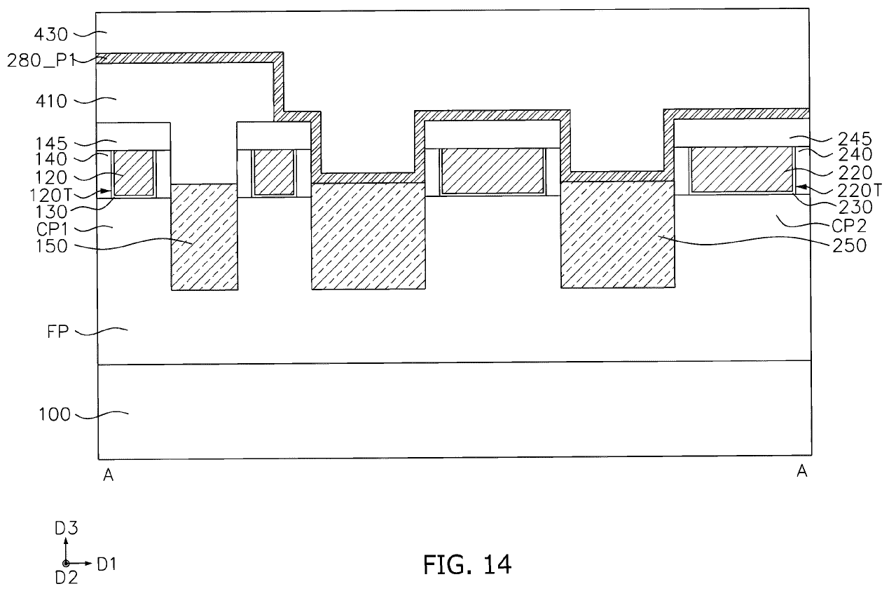

Referring to FIG. 14, a first spacer liner 280_P1 and a mask layer 430 may be formed on the protective layer 410, the second source/drain pattern 250, and the second gate capping pattern 245.

Specifically, the first spacer liner 280_P1 may be formed along the profile of the protective layer 410, the second gate capping pattern 245, the second gate spacer 240, and the second source/drain pattern 250. In some example embodiments, the first spacer liner 280_P1 may be conformally formed.

The mask layer 430 may be formed on the first spacer liner 280_P1. For example, the mask layer 430 may be a spin on hardmask (SOH).

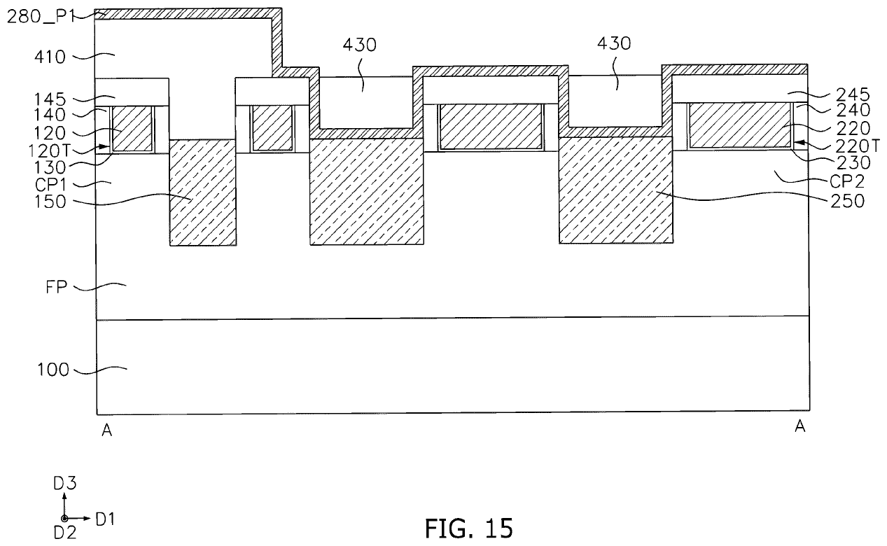

Referring to FIG. 15, a portion of the mask layer 430 may be removed. For example, the portion of the mask layer 430 may be removed by a first etching process. The mask layer 430 may remain on a portion of the first spacer liner 280_P1, that is, on the first spacer liner 280_P1 that is disposed on the second source/drain pattern 250.

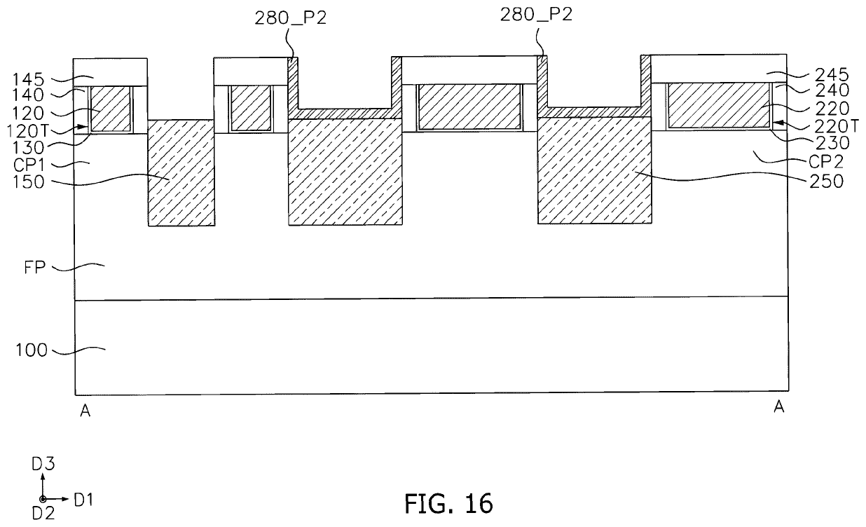

Referring to FIGS. 15 and 16, a portion of the first spacer liner 280_P1 may be removed, and the protective layer 410 and the mask layer 430 may be removed.

Specifically, the first spacer liner 280_P1 and the protective layer 410 may be removed to form a second spacer liner 280_P2. The uppermost portion of the second spacer liner 280_P2 may be disposed at the same or similar level as an upper surface of the second gate capping pattern 245. The second spacer liner 280_P2 may cover the upper surface of the second source/drain pattern 250. The protective layer 410 may be removed to expose the upper surface of the first source/drain pattern 150 and the upper surface of the first gate capping pattern 145.

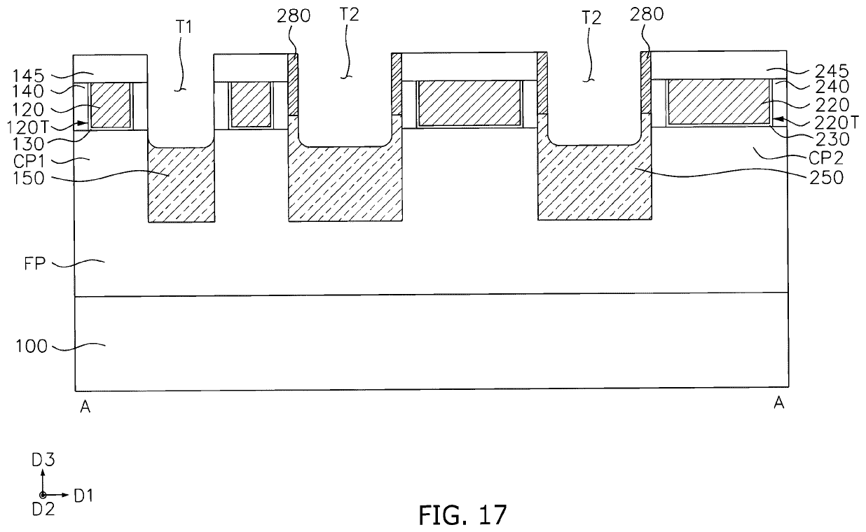

Referring to FIGS. 16 and 17, a first contact trench T1 and a second contact trench T2 may be formed by a second etching process.

Specifically, a portion of the first source/drain pattern 150 may be removed by the second etching process, and the first contact trench T1 may be formed. In addition, a portion of the second source/drain pattern 250 may be removed by the second etching process, and the second contact trench T2 may be formed. In this case, a portion of the second spacer liner 280_P2 may be removed to form the contact spacer 280.

The first contact trench T1 may expose the first source/drain pattern 150. The second contact trench T2 may expose the second source/drain pattern 250. The second etching process may be performed using the contact spacer 280 as an etching mask. That is, the second contact trench T2 may be formed between the contact spacers 280. The second etching process may be an etching process that uses a mask patterned with KrF or ArF as an etching mask.

As the semiconductor devices become smaller, fine processes are required. Accordingly, in the process of forming a contact on the source/drain pattern, a photolithography process using extreme ultra violet (EUV) may be performed for fine patterning. However, the photolithography process using EUV is expensive and the manufacturing cost of semiconductor devices may increase. Therefore, by performing the second etching process using a mask patterned with a KrF or an ArF photolithography process as an etching mask, the manufacturing cost of the semiconductor device may be reduced.

On the other hand, with the semiconductor device according to some example embodiments, an etching mask may be patterned with KrF or ArF which is relatively inexpensive compared to EUV. For example, the protective layer 410 may be formed on the first source/drain pattern 150 by using KrF or ArF. The contact spacer 280 may be formed, and the first contact trench T1 and the second contact trench T2 may also be formed.

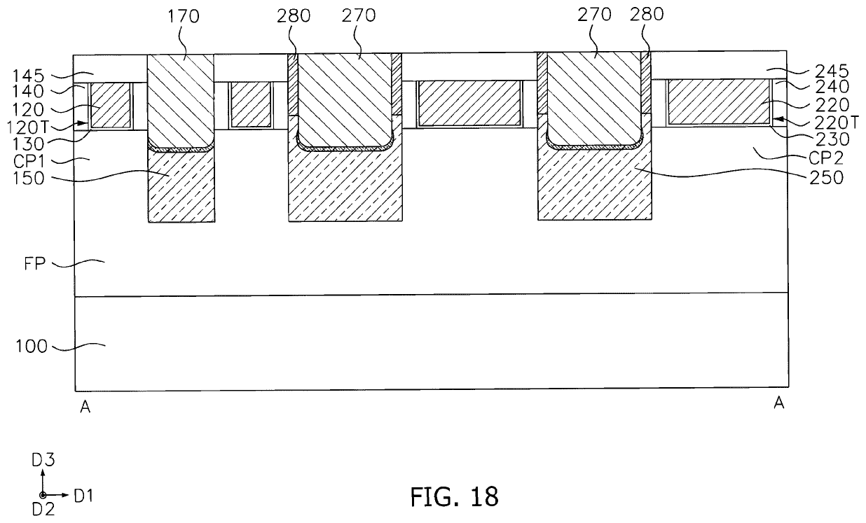

Referring to FIGS. 17 and 18, the first source/drain contact 170 may be formed on the first source/drain pattern 150, and the second source/drain contact 270 may be formed on the second source/drain pattern 250. The first source/drain contact 170 may fill the first contact trench T1. The second source/drain contact 270 may fill the second contact trench T2.

Referring to FIG. 2, the upper wiring structure 300 may be formed on the first gate capping pattern 145, the second gate capping pattern 245, the first source/drain contact 170, and the second source/drain contact 270. Accordingly, the semiconductor device according to some example embodiments may be provided.

Although some example embodiments of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the example embodiments described above are illustrative and non-limiting in all respects.

1. A semiconductor device, comprising:
a substrate;
a first channel pattern on the substrate, the first channel pattern having a first width in a first direction;
a first gate electrode extending in a second direction on the first channel pattern, the second direction crossing the first direction;
a first gate capping pattern on an upper surface of the first gate electrode;
a second channel pattern spaced apart from the first channel pattern in the first direction, the second channel pattern having a second width in the first direction;
a second gate electrode extending in the second direction on the second channel pattern;
a second gate capping pattern on an upper surface of the second gate electrode;
a source/drain pattern on at least one side of the second channel pattern;
a first source/drain contact connected to the source/drain pattern;
a second source/drain contact spaced apart from the first source/drain contact in the second direction;
a contact isolation film between the first source/drain contact and the second source/drain contact; and
a first contact spacer between the contact isolation film and the first source/drain contact,
wherein the second width is greater than the first width.

2. The semiconductor device according to claim 1, wherein the first contact spacer surrounds at least a portion of a side surface of the first source/drain contact.

3. The semiconductor device according to claim 1, wherein the first contact spacer is on a side surface of the second gate capping pattern.

4. The semiconductor device according to claim 1, wherein the first source/drain contact overlaps with the second source/drain contact in the second direction.

5. The semiconductor device according to claim 1, wherein
the first source/drain contact comprises
a first side surface and a second side surface opposing each other in the first direction, and
a third side surface and a fourth side surface opposing each other in the second direction, and
the first contact spacer is in contact with each of the first to fourth side surfaces of the first source/drain contact.

6. The semiconductor device according to claim 1, wherein a bottom surface of the first contact spacer is in contact with the source/drain pattern.

7. The semiconductor device according to claim 1, wherein the contact isolation film and the first contact spacer comprise different materials.

8. The semiconductor device according to claim 1, further comprising:
a second contact spacer between the contact isolation film and the second source/drain contact,
wherein the second contact spacer surrounds at least a portion of a side surface of the second source/drain contact.

9. The semiconductor device according to claim 1, further comprising:
a silicide film between the source/drain pattern and the first source/drain contact.

10. The semiconductor device according to claim 1, wherein a width of the contact isolation film in the first direction is greater than a width of the first source/drain contact in the first direction.

11. The semiconductor device according to claim 1, further comprising:
a gate spacer on a side surface of the second gate electrode,
wherein the first contact spacer is in contact with the gate spacer.

12. The semiconductor device according to claim 1, wherein a distance from an upper surface of the substrate to an upper surface of the first source/drain contact is a same distance as a distance from the upper surface of the substrate to an upper surface of the first contact spacer.

13. The semiconductor device according to claim 1, wherein
the first channel pattern comprises a plurality of first sheet patterns spaced apart in a third direction,
the second channel pattern comprises a plurality of second sheet patterns spaced apart in the third direction, and
the third direction is perpendicular to an upper surface of the substrate.

14. A semiconductor device, comprising:
a substrate;
a first channel pattern on the substrate, the first channel pattern having a first width in a first direction;
a second channel pattern spaced apart from the first channel pattern in the first direction, the second channel pattern having a second width in the first direction;
a first source/drain pattern on at least one side of the first channel pattern;
a first source/drain contact on the first source/drain pattern;
a second source/drain pattern on at least one side of the second channel pattern;
a second source/drain contact on the second source/drain pattern;
a third source/drain contact spaced apart from the second source/drain contact in a second direction, the second direction crossing the first direction;
a contact spacer surrounding a side surface of the second source/drain contact; and
a first contact isolation film between the second source/drain contact and the third source/drain contact and in contact with the contact spacer,
wherein the second width is greater than the first width.

15. The semiconductor device according to claim 14, wherein a width of the first source/drain contact in the first direction is less than a width of the second source/drain contact in the first direction.

16. The semiconductor device according to claim 14, further comprising:
a second contact isolation film on a side surface of the first source/drain contact and overlapping the side surface of the first source/drain contact in the second direction,
wherein a width of the second contact isolation film in the second direction is less than a width of the first contact isolation film in the second direction.

17. The semiconductor device according to claim 16, wherein a width of the first source/drain contact in the first direction is a same width as a width of the second contact isolation film in the first direction.

18. The semiconductor device according to claim 14, further comprising:
a gate electrode on the second channel pattern and extending in the second direction; and
a gate spacer on a side surface of the gate electrode, wherein
at least a portion of the contact spacer is between the gate spacer and the second source/drain contact.

19. The semiconductor device according to claim 18, further comprising:
a gate capping pattern on an upper surface of the gate electrode,
wherein an upper surface of the gate capping pattern is on a same plane as an upper surface of the second source/drain contact.

20. A semiconductor device, comprising:
a substrate;
a first channel pattern on the substrate, the first channel pattern having a first width in a first direction;
a first gate electrode extending in a second direction on the first channel pattern, the second direction crossing the first direction;
a first gate capping pattern on an upper surface of the first gate electrode;
a second channel pattern spaced apart from the first channel pattern in the first direction, the second channel pattern having a second width greater than the first width in the first direction;
a second gate electrode extending in the second direction on the second channel pattern;
a second gate capping pattern on an upper surface of the second gate electrode;
a gate spacer on a side surface of the second gate electrode;
a source/drain pattern on at least one side of the second channel pattern;
a first source/drain contact on the source/drain pattern;
a second source/drain contact spaced apart from the first source/drain contact in the second direction;
a contact isolation film between the first source/drain contact and the second source/drain contact; and
a contact spacer between the contact isolation film and the first source/drain contact,
wherein the contact spacer surrounds at least a portion of a side surface of the first source/drain contact, and
at least a portion of the contact spacer is in contact with a side surface of the gate capping pattern.
